(19) United States
(12) Patent Application Publication
(10) Pub. No.: US 2026/0195226 A1
(43) Pub. Date: Jul. 9, 2026

(54) METHOD FOR TESTING CHIP AND ASSOCIATED SERIAL BUS TIMING CHECK MODULE

(71) Applicant: Realtek Semiconductor Corp., HsinChu (TW)

(72) Inventors: WEN JI, Suzhou City (CN); XIANGHUA SHEN, Suzhou City (CN); Yingxue Wang, Suzhou City (CN); XiangYu Zhang, Suzhou City (CN)

(73) Assignee: Realtek Semiconductor Corp., HsinChu (TW)

(21) Appl. No.: 19/406,968

(22) Filed: Dec. 3, 2025

(30) Foreign Application Priority Data
Jan. 7, 2025 (CN) 202510022507.5

(51) Int. Cl. G06F 11/263; G06F 11/22

(52) U.S. Cl. CPC G06F 11/263; G06F 11/2221

(57) ABSTRACT

The present invention provides a method for testing a chip, which includes the steps of: receiving a clock signal and a data signal from a verification module; shaping the clock signal and/or the data signal to generate a constructed clock signal and a constructed data signal; inputting the constructed clock signal and the constructed data signal into the chip; receiving an output clock signal and an output data signal from the chip; and performing timing checks on the output clock signal and the output data signal to generate an output check clock signal and a checked data signal to the verification module.

### BACKGROUND OF THE INVENTION

### Field of the Invention

This invention relates to a timing check method for a serial bus.

### Description of the Prior Art

In integrated circuit (IC) design, rigorous verification is typically performed prior to tape-out to ensure that various functionalities of the chip meet design specifications. For current System-on-Chip (SoC) products, testing is commonly conducted on serial bus integrated therein, such as Serial Peripheral Interface (SPI), Inter-Integrated Circuit (I2C), and Media Independent Interface Management (MIIM). With the trend towards miniaturization, high speed operation, and increasing intelligence of electronic devices, the application domains of chips have broadened, and their operating environments have become more complex, leading to more stringent timing requirements for serial buses. For serial bus modules on a chip, in addition to functional verification to ensure that the functional modules operate correctly according to design specifications, timing verification is also necessary to ensure that the bus timing meets the required specifications. The timing relationships within a bus module are crucial; once timing issues occur during data transmission, the correctness of the data transfer cannot be guaranteed.

Furthermore, most timing checks are currently performed on the chip during the later stages of product development, close to the finalization. However, due to the long development cycle and high debugging costs associated with chip design, it is often not feasible to rapidly adjust the chip design at such a late stage of product development.

### SUMMARY OF THE INVENTION

Therefore, one of the objectives of the present invention is to provide a serial bus timing check module that can effectively and rapidly perform timing checks on the serial bus of a chip in the early stages of product development, thereby solving the problems described in the prior art.

In one embodiment of the present invention, a method for testing a chip comprises the steps of: receiving a clock signal and a data signal from a verification module; shaping the clock signal and/or the data signal to generate a constructed clock signal and a constructed data signal; inputting the constructed clock signal and the constructed data signal into the chip; receiving an output clock signal and an output data signal from the chip; and performing timing checks on the output clock signal and the output data signal to generate an output check clock signal and a checked data signal to the verification module.

In one embodiment of the present invention, a serial bus timing check module comprising a construction module and a check module is disclosed. The construction module is configured to receive a clock signal and a data signal from a verification module, shape the clock signal and/or the data signal to generate a constructed clock signal and a constructed data signal, and input the constructed clock signal and the constructed data signal into a chip. The check module is configured to receive an output clock signal and an output data signal from the chip, perform timing checks on the output clock signal and the output data signal to generate an output check clock signal and a checked data signal to the verification module.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a system according to an embodiment of the present invention.

FIG. 2 is a schematic diagram illustrating the adjustment of valid intervals of a signal according to an embodiment of the present invention.

FIG. 3 is a timing diagram illustrating a plurality of signals of a construction module according to an embodiment of the present invention.

FIG. 4 is a timing diagram illustrating a plurality of signals of a construction module according to an embodiment of the present invention.

FIG. 5 is a timing diagram illustrating a plurality of signals of a construction module according to an embodiment of the present invention.

FIG. 6 is a timing diagram illustrating a plurality of signals of a check module according to an embodiment of the present invention.

FIG. 7 is a flowchart illustrating a method for testing a chip according to an embodiment of the present invention.

### DETAILED DESCRIPTION

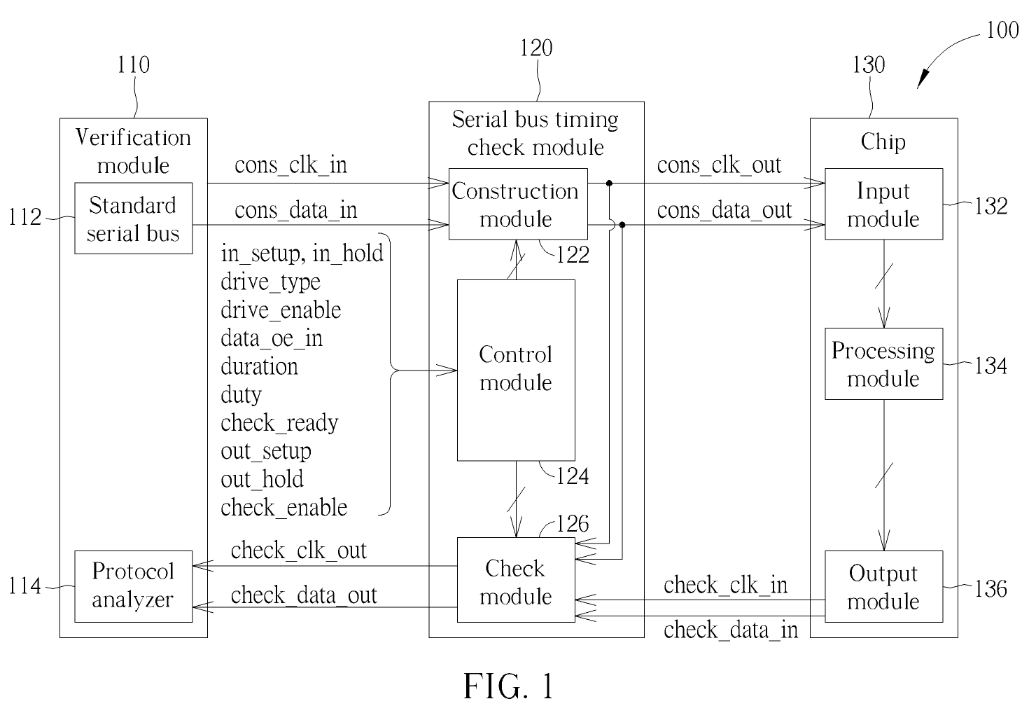

FIG. 1 is a schematic diagram of a system 100 according to an embodiment of the present invention. As shown in FIG. 1, the system 100 includes a verification module 110, a serial bus timing check module 120, and a chip 130. The verification module 110 includes a standard serial bus 112 and a protocol analyzer 114. The serial bus timing check module 120 includes a construction module 122, a control module 124, and a check module 126. The chip 130 includes an input module 132, a processing module 134, and an output module 136. In this embodiment, the chip 130 can be an early-stage chip design in product development or a Field Programmable Gate Array (FPGA). In this embodiment, the serial bus timing check module 120 can be implemented using a dedicated hardware circuit or by executing program code via a processor in software.

One operational aspect of the system 100 is as follows. The verification module 110 is configured to generate a clock signal cons_clk_in and a data signal cons_data_in to the serial bus timing check module 120. The construction module 122 within the serial bus timing check module 120, under the control of the control module 124, shapes the clock signal cons_clk_in and/or the data signal cons_data_in to generate a constructed clock signal cons_clk_out and a constructed data signal cons_data_out, and inputs the constructed clock signal cons_clk_out and the constructed data signal cons_data_out to the chip 130. Subsequently, the input module 132 of the chip 130 receives the constructed clock signal cons_clk_out and the constructed data signal cons_data_out from the serial bus timing check module 120, and then the processing module 134 performs related processing.

Another operational aspect of the system 100 is as follows. After the processing module 134 actively or passively outputs a clock signal check_clk_in and an output data signal check_data_in, the output module 136 transmits the clock signal check_clk_in and the output data signal check_data_in to the check module 126 of the serial bus timing check module 120. The check module 126 performs timing checks on the output clock signal check_clk_in and the output data signal check_data_in, and generates an output check clock signal check_clk_out and a checked data signal check_data_out to the protocol analyzer 114 in the verification module 110 for determining whether the signals output by the chip 130 comply with the communication protocol and whether the output information meets expectations. In one embodiment, the check module 126 may also perform timing checks on the constructed clock signal cons_clk_out and the constructed data signal cons_data_out, but without subsequent operations, that is, without transmitting a check result of the constructed clock signal cons_clk_out and the constructed data signal cons_data_out to the verification module 110.

In this embodiment, the output clock signal check_clk_in and the output data signal check_data_in generated by the processing module 134 may or may not have a specific correlation with the constructed clock signal cons_clk_out and the constructed data signal cons_data_out. For example, the processing module 134 can include two parts, one configured to receive and process the constructed clock signal cons_clk_out and the constructed data signal cons_data_out, and the other configured to generate the output clock signal check_clk_in and the output data signal check_data_in to the output module 136.

In this embodiment, the control module 124 can control the construction module 122 to adjust the clock signal cons_clk_in and/or the data signal cons_data_in through a plurality of control signals, so as to generate constructed clock signals cons_clk_out and constructed data signals cons_data_out with different characteristics, thereby providing the capability to test the chip 130 in processing these signals. In FIG. 1, the plurality of control signals received by the control module 124 includes a setup time in_setup and a hold time in_hold used by the construction module 122, a drive type drive_type, a drive enable drive_enable, a data input direction data_oe_in, a full cycle duration, a duty cycle ‘duty’, a check ready check_ready, and also includes a setup time out_setup and a hold time out_hold used by the check module 126, a check enable check_enable, and so on.

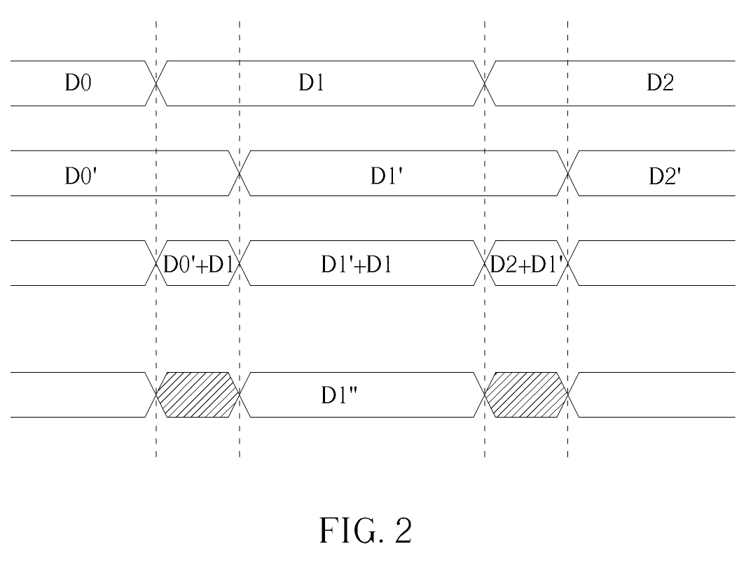

In one embodiment, the construction module 122 can adjust the valid interval of the data signal cons_data_in to generate the constructed data signal cons_data_out. Referring to FIG. 2, assuming the data signal cons_data_in sequentially includes data D2, D1, and D0, the construction module 122 can delay the data signal cons_data_in by a certain period to generate data D2', D1', and D0'. Subsequently, a logic operation is performed on data D2, D1, D0 and data D2', D1', D0' to generate the constructed data signal cons_data_out. In the example shown in FIG. 2, assuming data D2, D1, and D0 are "0", "1", and "0" respectively, the construction module 122 can perform an AND operation on D2, D1, D0 and D2', D1', D0' to generate the constructed data signal cons_data_out, wherein the data D1" in the constructed data signal cons_data_out has a shorter valid interval compared to the original data D1.

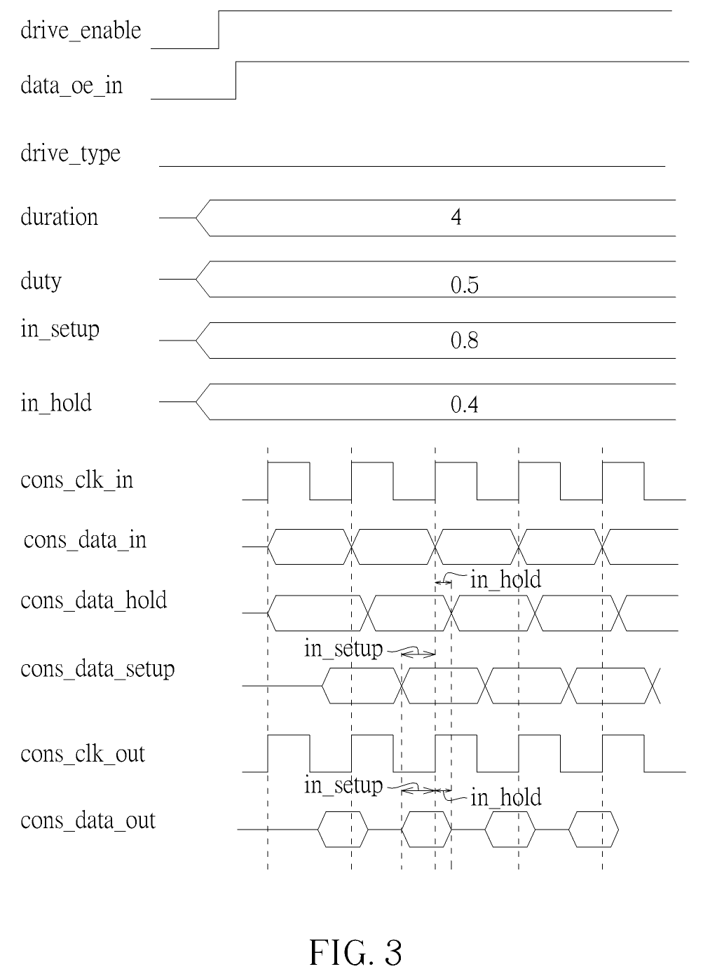

FIG. 3 is a timing diagram illustrating a plurality of signals of the construction module 122 according to an embodiment of the present invention. When the drive enable signal drive_enable is at a high voltage level (logic "1"), it indicates that the construction module 122 is enabled and starts operating. When the data input direction signal data_oe_in is at logic "1", it indicates that the construction module 122 is currently outputting the constructed data signal cons_data_out to the chip 130. When the drive type signal drive_type is at logic "0", it indicates that the construction module 122 drives the data signal cons_data_in at the rising edge of the clock signal cons_clk_in, and the chip 130 also samples the constructed data signal cons_data_out at the rising edge of the constructed clock signal cons_clk_out after receiving the constructed clock signal cons_clk_out and the constructed data signal cons_data_out. The values within the full cycle duration, duty cycle, setup time in_setup, and hold time in_hold used by the construction module 122 are settings made by engineers based on their needs. The construction module 122 first delays the data signal cons_data_in by a first delay amount (e.g., the hold time in_hold) to generate a first delayed signal cons_data_hold, then delays the data signal cons_data_in by a second delay amount (e.g., duration - in_setup) to generate a second delayed signal cons_data_setup, and finally performs a logic operation (e.g., an AND operation) on the first delayed signal cons_data_hold and the second delayed signal cons_data_setup to generate the constructed data signal cons_data_out. Furthermore, in the embodiment shown in FIG. 3, the constructed clock signal cons_clk_out is equal to the clock signal cons_clk_in.

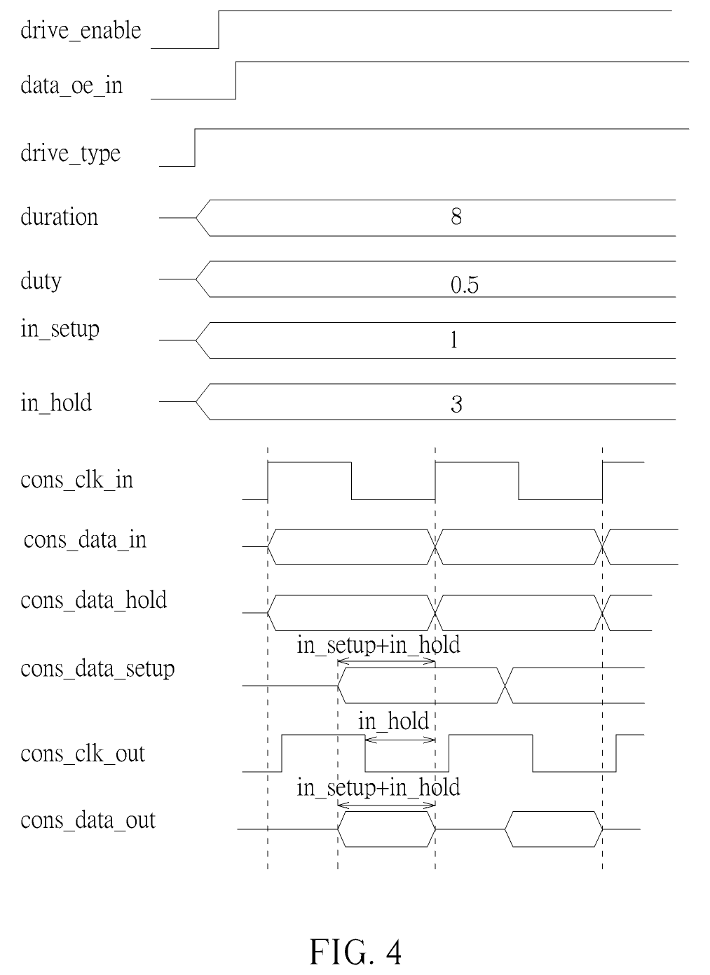

FIG. 4 is a timing diagram illustrating a plurality of signals of the construction module 122 according to another embodiment of the present invention. When the drive enable signal drive_enable is at logic "1", it indicates that the construction module 122 is enabled and starts operating. When the data input direction signal data_oe_in is at logic "1", it indicates that the construction module 122 is currently outputting the constructed data signal cons_data_out to the chip 130. When the drive type signal drive_type is at logic "1", it indicates that the construction module 122 drives the data signal cons_data_in at the rising edge of the clock signal cons_clk_in, and the chip 130 samples the constructed data signal cons_data_out at the falling edge of the constructed clock signal cons_clk_out after receiving the constructed clock signal cons_clk_out and the constructed data signal cons_data_out. The values within the full cycle duration, duty cycle, setup time in_setup, and hold time in_hold used by the construction module 122 are settings made by engineers based on their needs. The construction module 122 first delays the data signal cons_data_in by a first delay amount (e.g., a delay amount of 0 or a very small value) to generate a first delayed signal cons_data_hold, then delays the data signal cons_data_in by a second delay amount (e.g., duration - in_hold - in_setup) to generate a second delayed signal cons_data_setup, and finally performs a logic operation (e.g., an AND operation) on the first delayed signal cons_data_hold and the second delayed signal cons_data_setup to generate the constructed data signal cons_data_out. Furthermore, in the embodiment shown in FIG. 4, the construction module 122 delays the clock signal cons_clk_in by a third delay amount to generate the constructed clock signal cons_clk_out, wherein the third delay amount can be the product of the full cycle and the duty cycle minus the hold time in_hold used by the construction module 122, i.e., (duration * duty - in_hold), but the present invention is not limited thereto.

As shown in the embodiments of FIG. 3 and FIG. 4, since the length of the valid interval of the constructed data signal cons_data_out is equal to the sum of the setup time in_setup and the hold time in_hold used by the construction module 122, engineers can simply test the limits that the chip 130 can recognize/process by setting the setup time in_setup and the hold time in_hold to their allowed minimum values. Furthermore, during the testing process, the aforementioned parameters can be arbitrarily modified according to the engineers' considerations, and different constructed data signals cons_data_out can be generated in real-time for testing purposes.

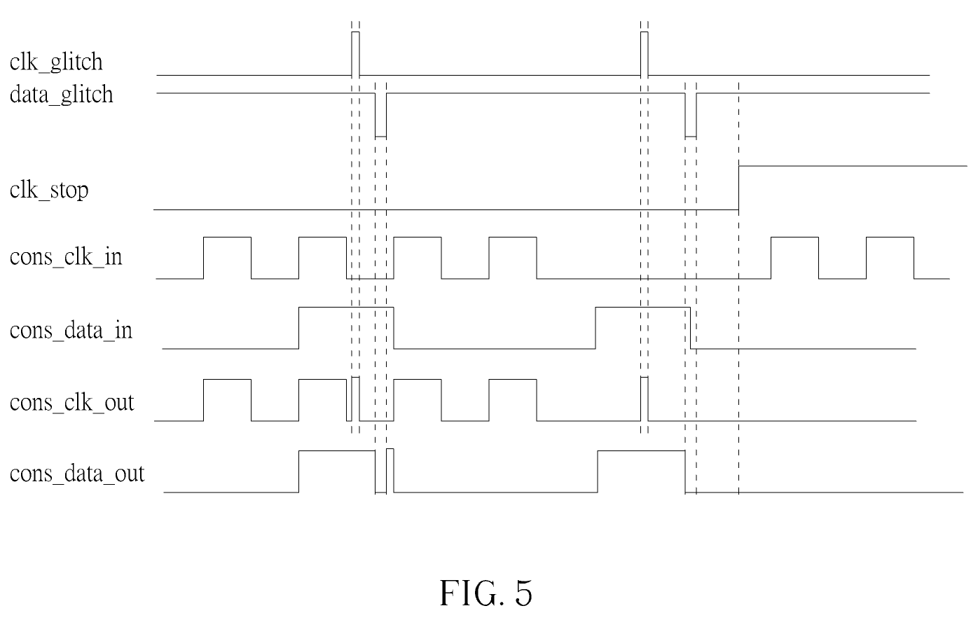

In one embodiment of the present invention, in addition to changing the valid interval of the data signal cons_data_in, the construction module 122 can also simulate situations where the clock signal cons_clk_in and/or the data signal cons_data_in are subjected to glitches, or where the clock signal cons_clk_in experiences clock stoppage. Specifically, reference is now made to FIG. 5, which is a timing diagram illustrating a plurality of signals of the construction module 122 according to another embodiment of the present invention. The clock glitch signal clk_glitch and the data glitch signal data_glitch are glitch signals received by the construction module 122 from an external source or generated internally. The clock stop signal clk_stop can be received by the construction module 122 from an external source or generated internally. The construction module 122 can perform at least one logic operation on the clock signal cons_clk_in and the clock glitch signal clk_glitch to obtain the constructed clock signal cons_clk_out. For example, the construction module 122 can obtain the constructed clock signal cons_clk_out by performing an OR gate operation on the clock signal cons_clk_in and the clock glitch signal clk_glitch, and then performing an AND gate operation with an inverted signal of the clock stop signal clk_stop. Furthermore, the construction module 122 can perform a logic operation on the data signal cons_data_in and the data glitch signal data_glitch to obtain the constructed data signal cons_data_out. For example, the construction module 122 can obtain the constructed data signal cons_data_out by performing an AND gate operation on the data signal cons_data_in and the data glitch signal data_glitch.

In the embodiment of FIG. 5, by intentionally adding interference (e.g., glitches) to the clock signal cons_clk_in and/or the data signal cons_data_in through the use of the construction module 122, the performance of the chip 130 when processing interfered signals can be tested.

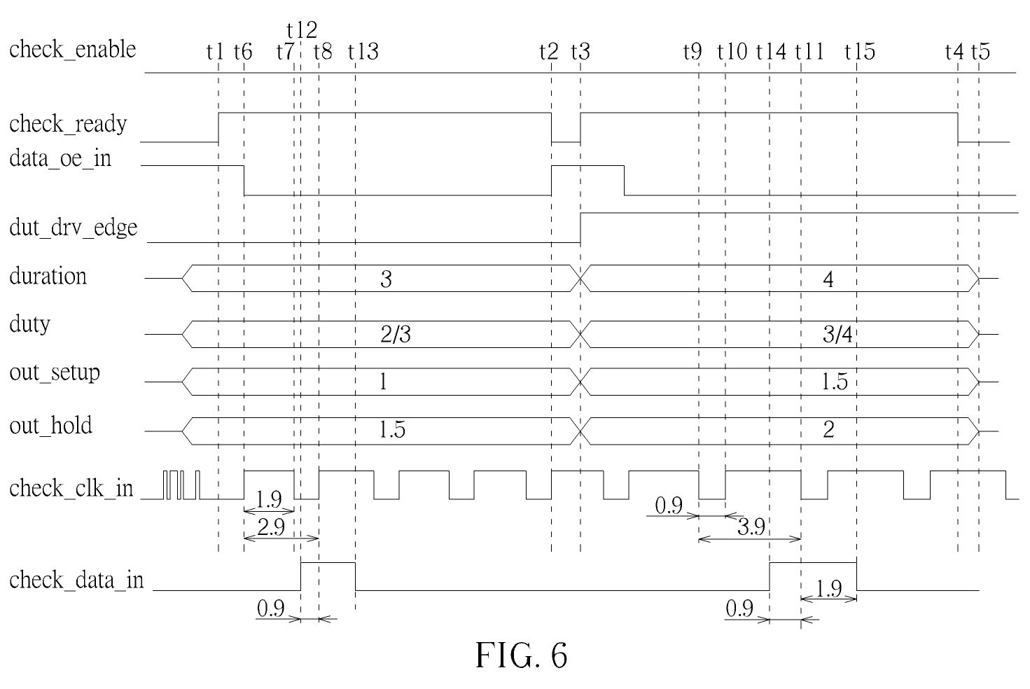

Regarding the operation of the check module 126, the check module 126 is used to perform timing checks on the output clock signal check_clk_in and the output data signal check_data_in, such as determining the frequency and duty cycle of the output clock signal check_clk_in, or determining the setup time and hold time when the output clock signal check_clk_in is used to sample the output data signal check_data_in. Specifically, reference is now made to FIG. 6, which is a timing diagram illustrating a plurality of signals of the check module 126 according to another embodiment of the present invention. When the check enable signal check_enable is at a high voltage level (logic "1"), it indicates that the check module 126 is enabled and starts operating. The check ready signal check_ready indicates the time interval for starting the check. Before time t1, the clock signal may be unstable, so it is necessary to wait for the signal to stabilize before configuring the check ready signal check_ready to "1". In FIG. 6, the time intervals t1 - t2 andt3 - t4 are time intervals during which the check can be started. The full cycle duration and duty cycle can be modified during the time interval when the check ready signal check_ready is "0". Furthermore, the check module 126 can use the system tasks $width and $period provided by Verilog to check the period and half-period of the output clock signal check_clk_in. For example, when the device under test drive edge dut_drive_edge is "0", times t6, t7, and t8 are used as reference points for checking, and when the device under test drive edge dut_drive_edge is "1", times t9, t10, and t11 are used as reference points for checking. The setup time out_setup and hold time out_hold used by the check module 126 are the minimum values that can satisfy the check, and they can be modified during the time interval when the check ready signal check_ready is "0". In the case where the data input direction signal data_oe_in is "0", the check module 126 can use the system task $setuphold provided by Verilog for checking. For example, when the device under test drive edge dut_drive_edge is "1", times t8, t12, and t13 are used as reference points for checking, and when the device under test drive edge dut_drive_edge is "0", times t11, t14, and t15 are used as reference points for checking. Furthermore, the numbers labeled in FIG. 6 are for reference only and are not limitations of the present invention.

In the embodiment of FIG. 6, the description focuses on the check module 126 performing timing checks on the output clock signal check_clk_in and the output data signal check_data_in. However, the check module 126 can also perform similar checks on the constructed clock signal cons_clk_out and the constructed data signal cons_data_out generated by the construction module 122.

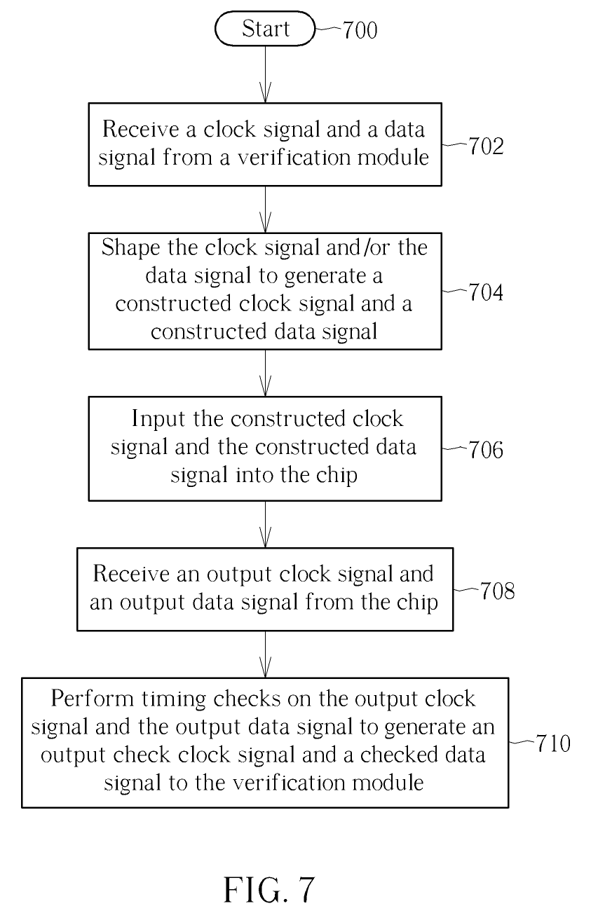

FIG. 7 is a flowchart illustrating a method for testing a chip according to an embodiment of the present invention. Referring to the content of the above embodiments, the flow is described as follows.

Step 700: The flow starts.

Step 702: Receive a clock signal and a data signal from a verification module.

Step 704: Shape the clock signal and/or the data signal to generate a constructed clock signal and a constructed data signal.

Step 706: Input the constructed clock signal and the constructed data signal into the chip.

Step 708: Receive an output clock signal and an output data signal from the chip.

Step 710: Perform timing checks on the output clock signal and the output data signal to generate an output check clock signal and a checked data signal to the verification module.

In summary, in the above embodiments of the present invention, by using the construction module 122 to adjust the clock signal cons_clk_in and/or the data signal cons_data_in to generate constructed clock signals cons_clk_out and constructed data signals cons_data_out with different characteristics, the capability of the chip 130 in processing these signals can be effectively tested in the early stages of chip development. This facilitates engineers in addressing any shortcomings of the chip 130. Furthermore, the serial bus timing check module 120 of the present invention has a simple architecture and can be applied to various different devices, thus providing convenience for engineers when verifying chip functionality.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for testing a chip, comprising:
receiving a clock signal and a data signal from a verification module;
shaping the clock signal and/or the data signal to generate a constructed clock signal and a constructed data signal;
inputting the constructed clock signal and the constructed data signal into the chip;
receiving an output clock signal and an output data signal from the chip; and
performing timing checks on the output clock signal and the output data signal to generate an output check clock signal and a checked data signal to the verification module.

2. The method of claim 1, wherein the step of shaping the clock signal and/or the data signal to generate the constructed clock signal and the constructed data signal comprises:
delaying the data signal by a first delay amount to generate a first delayed signal;
delaying the data signal by a second delay amount to generate a second delayed signal; and
performing a logic operation on the first delayed signal and the second delayed signal to generate the constructed data signal.

3. The method of claim 2, wherein the step of shaping the clock signal and/or the data signal to generate the constructed clock signal and the constructed data signal is performed by a construction module, the first delay amount is a hold time used by the construction module, and the second delay amount is a duration used by the construction module minus a setup time used by the construction module.

4. The method of claim 2, wherein the step of shaping the clock signal and/or the data signal to generate the constructed clock signal and the constructed data signal is performed by a construction module, the first delay amount is zero, and the second delay amount is a duration used by the construction module minus a setup time used by the construction module and further minus a hold time used by the construction module.

5. The method of claim 4, wherein the step of shaping the clock signal and/or the data signal to generate the constructed clock signal and the constructed data signal further comprises:
delaying the clock signal by a third delay amount to generate the constructed clock signal.

6. The method of claim 1, wherein the step of shaping the clock signal and/or the data signal to generate the constructed clock signal and the constructed data signal comprises:
performing a logic operation on the clock signal and a clock glitch signal to generate the constructed clock signal.

7. The method of claim 1, wherein the step of shaping the clock signal and/or the data signal to generate the constructed clock signal and the constructed data signal comprises:
performing a logic operation on the data signal and a data glitch signal to obtain the constructed data signal.

8. The method of claim 1, wherein the step of performing the timing checks on the output clock signal and the output data signal to generate the output check clock signal and the checked data signal to the verification module comprises:
performing the timing checks on the output clock signal and the output data signal to generate the output check clock signal and the checked data signal to the verification module; and
performing the timing checks on the constructed clock signal and the constructed data signal without transmitting a check result of the constructed clock signal and the constructed data signal to the verification module.

9. A serial bus timing check module, comprising:
a construction module configured to receive a clock signal and a data signal from a verification module, shape the clock signal and/or the data signal to generate a constructed clock signal and a constructed data signal, and input the constructed clock signal and the constructed data signal into a chip; and
a check module configured to receive an output clock signal and an output data signal from the chip, perform timing checks on the output clock signal and the output data signal to generate an output check clock signal and a checked data signal to the verification module.

10. The serial bus timing check module of claim 9, wherein the construction module delays the data signal by a first delay amount to generate a first delayed signal, delays the data signal by a second delay amount to generate a second delayed signal, and performs a logic operation on the first delayed signal and the second delayed signal to generate the constructed data signal.

11. The serial bus timing check module of claim 10, wherein the first delay amount is a hold time used by the construction module, and the second delay amount is a duration used by the construction module minus a setup time used by the construction module.

12. The serial bus timing check module of claim 10, wherein the first delay amount is zero, and the second delay amount is a duration used by the construction module minus a setup time used by the construction module and further minus a hold time used by the construction module.

13. The serial bus timing check module of claim 12, wherein the construction module delays the clock signal by a third delay amount to generate the constructed clock signal.

14. The serial bus timing check module of claim 9, wherein the construction module performs a logic operation on the clock signal and a clock glitch signal to generate the constructed clock signal.

15. The serial bus timing check module of claim 9, wherein the construction module performs a logic operation on the data signal and a data glitch signal to obtain the constructed data signal.

16. The serial bus timing check module of claim 9, wherein the check module performs the timing checks on the output clock signal and the output data signal to generate the output check clock signal and the checked data signal to the verification module; and the check module performs the timing checks on the constructed clock signal and the constructed data signal without transmitting a check result of the constructed clock signal and the constructed data signal to the verification module.
